(19) United States
(12) Patent Application Publication
(10) Pub. No.: US 2026/0123238 A1
(43) Pub. Date: Apr. 30, 2026

(54) DISPLAY DEVICE, ELECTRONIC DEVICE, AND METHOD OF MANUFACTURING THE DISPLAY DEVICE

(71) Applicant: Samsung Display Co., Ltd., Yongin-si (KR)

(72) Inventors: Jinyeol LEE, Yongin-si (KR); Geun-ho Lee, Yongin-si (KR)

(73) Assignee: Samsung Display Co., Ltd., Yongin-si (KR)

(21) Appl. No.: 19/308,674

(22) Filed: Aug. 25, 2025

(30) Foreign Application Priority Data
Oct. 30, 2024 (KR) 10-2024-0150557

(51) Int. Cl. H10K 59/80; G06F 3/044; H10K 59/131; H10K 59/40

(52) U.S. Cl. CPC H10K 59/872; G06F 3/0446; H10K 59/131; H10K 59/40

(57) ABSTRACT

A display device may include a display extending at least partially in a first direction and a second direction that crosses the first direction; a window on the display in a third direction that crosses the first direction and the second direction; a connection circuit board connected to the display on a first side of the display; a main circuit board on a rear surface of the display in a fourth direction, opposite to the third direction, and connected to the connection circuit board; and a cover part overlapping with the connection circuit board and the main circuit board, wherein a first side of the cover part is in contact with a lower surface of the window in the fourth direction.

### CROSS-REFERENCE TO RELATED APPLICATION(S)

This application claims priority to and the benefit of Korean Patent Application No. 10-2024-0150557, filed on Oct. 30, 2024, in the Korean Intellectual Property Office, the disclosure of which is incorporated by reference herein in its entirety.

### BACKGROUND

### 1. Field

Some embodiments of the present disclosure relate to a display device, an electronic device, and a method of manufacturing the display device. More particularly, some embodiments of the present disclosure relate to a display device with improved reliability, an electronic device, and a method of manufacturing the display device.

### 2. Description of Related Art

Display devices, such as televisions, monitors, smart phones, and tablet computers, which provide images to users, may include a display panel that displays the images. Various display panels, such as, a liquid crystal display panel, an organic light emitting display panel, an electrowetting display panel, and an electrophoretic display panel, are being developed as the display panel.

A circuit board may be connected to a display panel through pads. As an example, pads of the circuit board, pads of the display panel, and pads of interconnected circuit boards may be required to be sufficiently and completely connected to ensure that control signals and image signals are transmitted to the display panel without distortion.

Information disclosed in this Background section has already been known to or derived by the inventors before or during the process of achieving the embodiments of the present application, or is technical information acquired in the process of achieving the embodiments. Therefore, it may contain information that does not form prior art that is already known to the public.

### SUMMARY

According to some embodiments of the present disclosure, a display device and an electronic device including the display device may be provided, wherein a driving chip of the display device may be protected from external static electricity.

According to some embodiments of the present disclosure, a display device may be provided and include: a display extending at least partially in a first direction and a second direction that crosses the first direction; a window on the display in a third direction that crosses the first direction and the second direction; a connection circuit board connected to the display on a first side of the display; a main circuit board on a rear surface of the display in a fourth direction, opposite to the third direction, and connected to the connection circuit board; and a cover part overlapping with the connection circuit board and the main circuit board, wherein a first side of the cover part is in contact with a lower surface of the window in the fourth direction.

According to some embodiments of the present disclosure, an electronic device may be provided and include: a housing; an electronic module in the housing; and a display device overlapping with the electronic module, the display device including: a display extending at least partially in a first direction and a second direction that crosses the first direction; a window on the display in a third direction that crosses the first direction and the second direction; a connection circuit board electrically connected to the display on a first side of the display; a main circuit board on a rear surface of the display in a fourth direction, opposite to the third direction, and connected to the connection circuit board; and a cover part overlapping with the connection circuit board and the main circuit board, wherein a first side of the cover part is in contact with a lower surface of the window in the fourth direction.

According to some embodiments of the present disclosure, a method of manufacturing a display device may be provided and include: connecting a display and a main circuit board with a connection circuit board, wherein the display extends at least partially in a first direction and a second direction that crosses the first direction, the main circuit board is on a rear surface of the display, and the connecting includes: connecting the connection circuit board to the display on one side of the display; and bending the connection circuit board, wherein the connection circuit board, which is bent, connects the display to the main circuit board. The method may further include: placing a window on the display in a third direction that crosses the first direction and the second direction; and overlapping the connection circuit board and the main circuit board with a cover part.

According to some embodiments of the present disclosure, a display device may include a cover part that makes contact with a lower surface of a window and a lower surface of a cover panel under the display module to cover a driving chip. The driving chip may be protected from external static electricity by the cover part. Thus, reliability of the display device may be enhanced.

According to some embodiments of the present disclosure, a manufacturing method of a display device may be provided and may include, forming a cover part, which may be attached to a lower surface of the window and a lower surface of a cover panel, after performing a process of forming the window. In this case, even when a defect is detected in the cover part, it becomes easier to separate the cover part from the window and the cover panel and to reattach the cover part to the window and the cover panel. Accordingly, a manufacturing yield of the display device may be improved.

### BRIEF DESCRIPTION OF DRAWINGS

FIG. 1 is an assembled perspective view of an electronic device according to an embodiment of the present disclosure;

FIG. 2 is an exploded perspective view of an electronic device according to an embodiment of the present disclosure;

FIG. 3 is a cross-sectional view of a display module according to an embodiment of the present disclosure;

FIG. 4 is a plan view of a display panel according to an embodiment of the present disclosure;

FIG. 5 is a plan view of an input sensing unit according to an embodiment of the present disclosure;

FIG. 6 is a cross-sectional view of a display module according to an embodiment of the present disclosure;

FIG. 7A is a cross-sectional view of a display device according to an embodiment of the present disclosure;

FIG. 7B is a cross-sectional view of a display device according to an embodiment of the present disclosure;

FIG. 8 is a cross-sectional view of a display device according to an embodiment of the present disclosure; and

FIGS. 9A to 9E are process views of a method of manufacturing a display device according to an embodiment of the present disclosure.

### DETAILED DESCRIPTION

Embodiments of the present disclosure may be variously modified and realized in many different forms, and thus non-limiting example embodiments will be described in detail below and shown in the drawings. However, embodiments of the present disclosure are not limited to the specific example embodiments. All modifications, equivalents, and/or replacements of embodiments of the present disclosure are included in the spirit and scope of the present disclosure.

In the present disclosure, it will be understood that when an element (or area, layer, or portion) is referred to as being “on,” “connected to”, or “coupled to” another element or layer, it can be directly on, connected, or coupled to the other element or layer or intervening elements or layers may be present.

Like numerals refer to like elements throughout. In the drawings, the thickness, ratio, and dimension of components may be exaggerated for effective description of the technical content.

As used herein, the term “and/or” may include any and all combinations of one or more of the associated listed items.

It will be understood that, although the terms “first,” “second,” etc., may be used herein to describe various elements, these elements is not limited by these terms. These terms are only used to distinguish one element from another element. Thus, a first element discussed below could be termed a second element without departing from the teachings of the present disclosure. As used herein, the singular forms, “a,” “an,” and “the” are intended to include the plural forms as well, unless the context clearly indicates otherwise.

Spatially relative terms, such as “beneath,” “below,” “lower,” “above,” “upper,” and the like, may be used herein for ease of description to describe one element or feature's relationship to another elements or features as shown in the figures.

Unless otherwise defined, all terms including technical and scientific terms used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “include” (or “comprise”) and/or “including” (or “comprising”) when used in this specification, specify the presence of stated features, integers, steps, operations, elements, and/or components, but do not preclude the presence or addition of one or more other features, integers, steps, operations, elements, components, and/or groups thereof.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c. It is to be understood that the term “substantially” as used herein with regard to thicknesses, widths, material composition, percentages, ranges, direction, etc., are meant to denote being close or approximate to, but not exactly. For example, the term “about” or “substantially” as used herein implies that a small margin of error may be present, such as 1% or less than the stated amount.

Hereinafter, non-limiting example embodiments of the present disclosure will be described with reference to accompanying drawings.

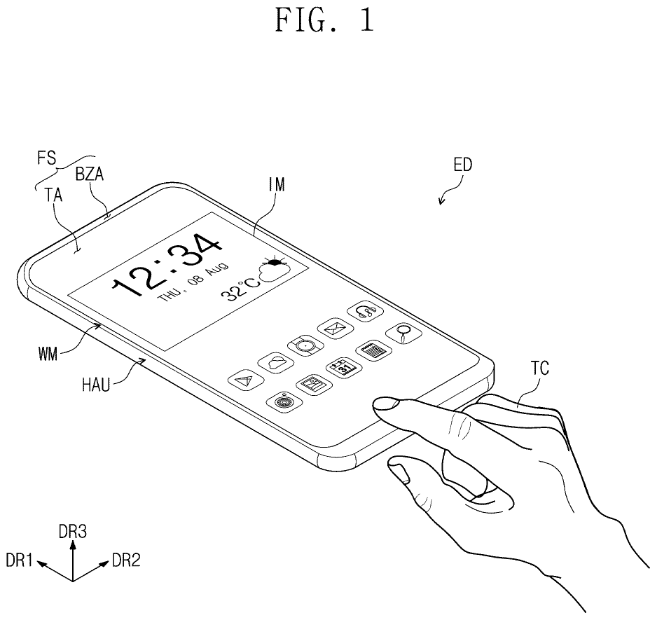

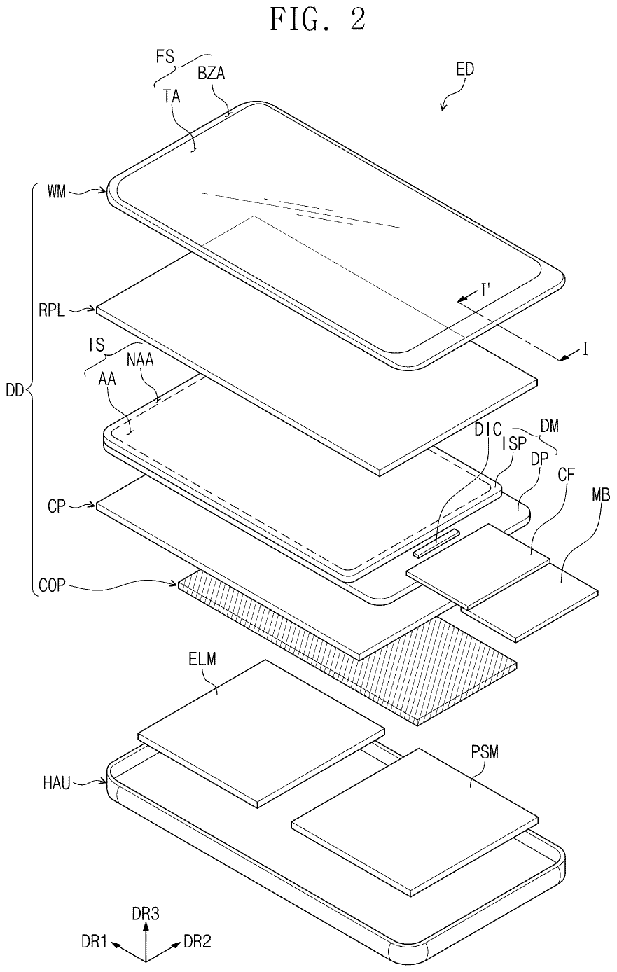

FIG. 1 is an assembled perspective view of an electronic device according to an embodiment of the present disclosure. FIG. 2 is an exploded perspective view of an electronic device according to an embodiment of the present disclosure.

Referring to FIGS. 1 and 2, the electronic device ED may be activated in response to electrical signals to display an image IM and to sense an external input TC. As an example, the electronic device ED may include devices such as a monitor, a mobile phone, a tablet computer, a navigation unit, a game unit, etc. However, these are merely examples, and the electronic device ED is not limited to any specific device. As a non-limiting example, the mobile phone will be described as the electronic device ED.

The electronic device ED may have a rectangular shape with long sides extending in a first direction DR1 and short sides extending in a second direction DR2 intersecting the first direction DR1 when viewed in a plane. However, the shape of the electronic device ED is not limited to the rectangular shape, and the electronic device ED may have a variety of shapes, such as a circular shape, a polygonal shape, etc.

In the present embodiment, a third direction DR3 may be substantially perpendicular to a plane defined by the first direction DR1 and the second direction DR2. Front (or upper) and rear (or lower) surfaces of each member of the electronic device ED may be opposite to each other in the third direction DR3, and a normal line direction of each of the front and rear surfaces may be substantially parallel to the third direction DR3. A separation distance between the front surface and the rear surface in the third direction DR3 may correspond to a thickness (e.g., a thickness of the electronic device ED) in the third direction DR3.

In the present disclosure, the expression “when viewed in a plane” may mean a state of being viewed in the third direction DR3. In the present disclosure, the expression “when viewed in a cross-section” may mean a state of being viewed in the first direction DR1 or the second direction DR2. Directions indicated by the first direction DR1, the second direction DR2, and the third direction DR3 may be relative to each other, and thus, the directions indicated by the first direction DR1, the second direction DR2, and the third direction DR3 may be changed to other directions.

The electronic device ED may be rigid or flexible. The term “flexible” used herein refers to the property of being able to be bent from a structure that is completely bent to a structure that is bent at the scale of a few nanometers. For example, in a case where the electronic device ED is flexible, the electronic device ED may be a curved electronic device, a rollable electronic device, or a foldable electronic device.

The electronic device ED may display the image IM through a display surface FS substantially parallel to the plane defined by the first direction DR1 and the second direction DR2. The image IM may include a still image as well as a video. FIG. 1 shows a clock widget and application icons as representative examples of the image IM.

The display surface FS of the electronic device ED may include only a plane or may further include a curved surface bent from at least one side of the plane. The display surface FS may be a front surface of the electronic device ED and may also be a front surface of a window WM. Hereinafter, the display surface FS may refer to both the display surface of the electronic device ED and the front surface of the window WM.

The electronic device ED may sense the external input TC applied from an outside of the electronic device ED. The external input TC may include inputs of various forms, such as, for example, force, pressure, temperature, light, etc. In the present embodiment, a touch input generated by a hand of a user and applied to the electronic device ED is described as an example of the external input TC. However, this is merely an example, and the external input TC may include an input from contact of a pen or a proximity input applied when close to the electronic device ED, such as hovering.

The electronic device ED may sense the user input through the display surface FS defined in the front surface of the electronic device ED and may respond to the sensed input. However, the area of the electronic device ED in which the external input is sensed is not limited to the front surface of the electronic device ED and may be changed depending on embodiment. As an example, the electronic device ED may sense the user input applied to a side or rear surface of the electronic device ED.

The electronic device ED may include a display device DD, an electronic module ELM, a power source module PSM (e.g., a power source), and a housing HAU. The display device DD may include the window WM, an optical layer RPL, the display module DM (e.g., a display), a cover panel CP, and a cover part COP. The window WM may be coupled with the housing HAU to form an exterior of the electronic device ED.

The window WM may be disposed on the display module DM. The window WM may cover the display module DM and may protect the display module DM from external impacts and scratches.

The window WM may include an optically transparent insulating material. As an example, the window WM may include a glass or a synthetic resin as its base film. The window WM may have a single-layer or multi-layer structure. As an example, the window WM having the multi-layer structure may include synthetic resin films attached to each other with an adhesive, or may include a glass film and a synthetic resin film attached to the glass film with an adhesive. The window WM may further include functional layers, such as an anti-fingerprint layer, a phase control layer, a hard coating layer, etc., disposed on an optically transparent substrate.

The front surface FS of the window WM may be the front surface FS of the electronic device ED. The front surface FS of the window WM may include a transmission area TA and a bezel area BZA.

The transmission area TA may be an optically transparent area. The transmission area TA may transmit the image IM provided from the display module DM. In the present embodiment, the transmission area TA is shown as having a quadrangular shape. However, the transmission area TA may have a variety of shapes according to embodiments.

The bezel area BZA may be an area with low light transmittance compared to a light transmittance of the transmission area TA. The bezel area BZA may be an area where a material having a selected color is printed. The bezel area BZA may block a light and may prevent components of the display module DM, which may be disposed to overlap the bezel area BZA, from being viewed from the outside.

The bezel area BZA may be adjacent to the transmission area TA, and the shape of the transmission area TA may be defined by the bezel area BZA. As an example, the bezel area BZA may be disposed outside the transmission area TA and may surround the transmission area TA. However, the bezel area BZA is not limited thereto or thereby. The bezel area BZA may be adjacent to only one side of the transmission area TA or may be disposed on a side surface of the electronic device ED rather than the front surface of the electronic device ED. In addition, the bezel area BZA may be omitted.

As shown in figures (e.g., FIG. 2), the optical layer RPL may be disposed between the display module DM and the window WM. The optical layer RPL may decrease a reflectance of the electronic device ED with respect to an external light. The optical layer RPL may include a retarder and/or a polarizer. The optical layer RPL may include at least a polarizing film. In this case, the optical layer RPL may be attached to the window WM by an adhesive. However, this is merely an example. As an example, the optical layer RPL may include a color filter.

The display module DM may be disposed between the window WM and the housing HAU. The display module DM may display the image IM and may sense the external input TC. The image IM may be displayed through a front surface IS of the display module DM. The front surface IS of the display module DM may include an active area AA and a peripheral area NAA.

The active area AA may be activated in response to electrical signals. As an example, the image IM may be displayed through the active area AA, and the external input TC may be sensed in the active area AA. The active area AA may overlap with at least a portion of the transmission area TA. Accordingly, the user may view the image IM or may provide the external input TC through the transmission area TA. However, this is merely an example, and an area where the image IM is displayed and an area where the external input TC is sensed is not particularly limited. For example, an area where the image IM is displayed and an area where the external input TC is sensed may be separated from each other in the active area AA.

The peripheral area NAA may be adjacent to the active area AA. For example, the peripheral area NAA may surround the active area AA. A driving circuit or a driving line to drive the active area AA may be arranged in the peripheral area NAA. The peripheral area NAA may overlap with at least a portion of the bezel area BZA, and components, which may be arranged in the peripheral area NAA, may be prevented from being viewed from the outside by the bezel area BZA.

The display module DM may include a display panel DP and an input sensing unit ISP (e.g., an input sensor). The display panel DP may display the image IM, and the input sensing unit ISP may sense the external input TC. These will be described in detail below.

The display panel DP may be flexible. The term “flexible” used herein refers to the property of being able to be bent, and the flexible display panel may include all structures from a structure that is completely bent to a structure that is partially bent. For example, the display panel DP may be a curved display panel or a foldable display panel. According to an embodiment, the display panel DP may be rigid as illustrated.

The display device DD according to an embodiment of the present disclosure may further include a driving chip DIC connected to the display panel DP, a connection circuit board CF, and a main circuit board MB.

The connection circuit board CF may connect the display panel DP and the main circuit board MB. One side of the connection circuit board CF, which may be adjacent to the display module DM, may be electrically connected to the display panel DP. The other side of the connection circuit board CF, which may be adjacent to the main circuit board MB, may be electrically connected to the main circuit board MB.

In FIG. 2, one connection circuit board CF that connects the display panel DP and the main circuit board MB is shown. However, embodiments of the present disclosure are not limited thereto or thereby. The connection circuit board CF may be provided in plural, and the connection circuit boards CF may connect the display panel DP and the main circuit board MB.

According to an embodiment, the connection circuit board CF may have a curvature and may be bent to a direction toward a rear surface of the display panel DP. As an example, the connection circuit board CF may be bent about a bending axis parallel to the second direction DR2. In this case, the main circuit board MB may be disposed on the rear surface of the display panel DP. For example, the main circuit board MB may be disposed on a rear surface of the cover panel CP.

The connection circuit board CF may be a flexible printed circuit board. The connection circuit board CF may apply electrical signals to the display panel DP to drive the display panel DP. The electrical signals may be generated by the connection circuit board CF or the main circuit board MB.

The driving chip DIC may be mounted on the display panel DP. However, according to an embodiment, the driving chip DIC may be mounted on the connection circuit board CF. The driving chip DIC may include driving elements to drive pixels of the display panel DP. The driving chip DIC may include a driving circuit, and the driving circuit may be implemented as an integrated circuit. The driving circuit may include a driving controller, a data driver, a voltage generator, and the like.

The main circuit board MB may include a main controller. The main circuit board MB may include signal lines to transmit control signals and image signals from the main controller to the connection circuit board CF and the display panel DP. The main circuit board MB may be a rigid printed circuit board or a flexible printed circuit board.

The electronic device ED may further include an input circuit board electrically connected to the input sensing unit ISP. The input circuit board may connect the input sensing unit ISP and the main circuit board MB. In the present embodiment, the input circuit board may be provided as a flexible circuit film and may connect the input sensing unit ISP and the main circuit board MB. The input circuit board may apply electrical signals to the input sensing unit ISP to drive the input sensing unit ISP. The electrical signals may be generated by the input circuit board or the main circuit board MB.

Each of the connection circuit board CF and the input circuit board may be connected to one main circuit board MB. According to an embodiment, one from among the connection circuit board CF and the input circuit board may not be connected to the main circuit board MB, but embodiments of the present disclosure are not limited thereto.

The cover panel CP may be disposed under the display panel DP. The cover panel CP may enhance resistance against a compressive force caused by external pressure. Accordingly, the cover panel CP may prevent the display module DM from being deformed. The cover panel CP may include a flexible plastic material, such as, for example, polyimide or polyethylene terephthalate. In addition, the cover panel CP may be a colored film with low light transmittance. The cover panel CP may absorb a light incident thereto from the outside. As an example, the cover panel CP may be a black synthetic resin film.

A support plate may be further disposed under the cover panel CP. The support plate may include a high-strength metal material. The support plate may include a reinforced fiber composite material. The support plate may include a reinforced fiber disposed in a matrix portion. The reinforced fiber may be a carbon fiber or a glass fiber. The matrix portion may include a polymer resin. The matrix portion may include a thermoplastic resin. As an example, the matrix portion may include a polyamide-based resin or a polypropylene-based resin. For example, the reinforced fiber composite material may be a carbon fiber reinforced plastic (CFRP) or a glass fiber reinforced plastic (GFRP).

The cover part COP may be disposed under the cover panel CP. The cover part COP may cover the main circuit board MB in the third direction DR3 and may cover the driving chip DIC in the first direction DR1. This will be described in detail below.

The electronic module ELM and the power source module PSM may be disposed under the display module DM. The electronic module ELM and the power source module PSM may be electrically connected to each other through a separate circuit board.

The power source module PSM may supply power for the operation of the electronic device ED. As an example, the power source module PSM may include a battery module.

The electronic module ELM may include various functional modules to operate the electronic device ED. As an example, the electronic module ELM may include a control module (e.g., a controller), a wireless communication module (e.g., a wireless communicator or interface), an image input module (e.g., an image inputter or interface), an audio input module (e.g., an audio inputter or interface), an audio output module (e.g., an audio outputter or interface), a memory, an optical module, and/or an external interface module (e.g., an external interface). The electronic module ELM may further include an antenna. The electronic module ELM may include a main circuit board, and the modules of the electronic module ELM may be mounted on the main circuit board or may be electrically connected to the main circuit board via a separate circuit board.

The control module of the electronic module ELM may control an overall operation of the electronic device ED. For example, the control module may activate or deactivate the display module DM in response to the user input. The control module may include at least one microprocessor. The optical module of the electronic module ELM may be or include a camera module, a proximity sensor, a biometric sensor that recognizes parts of a user's body (e.g., fingerprint, iris, or face), and/or a small lamp that emits a light.

The housing HAU may be coupled with the window WM to provide an inner space in which the display module DM, the electronic module ELM, the power source module PSM, the connection circuit board CF, and the main circuit board MB are accommodated. The housing HAU may include a material with a relatively high rigidity. For example, the housing HAU may include a glass, plastic, or metal material or a plurality of frames and/or plates of combinations thereof. The housing HAU may protect the components of the electronic device ED, which are accommodated in the housing HAU, by absorbing impacts applied from the outside and/or blocking a foreign substance or moisture from entering the electronic device ED from the outside.

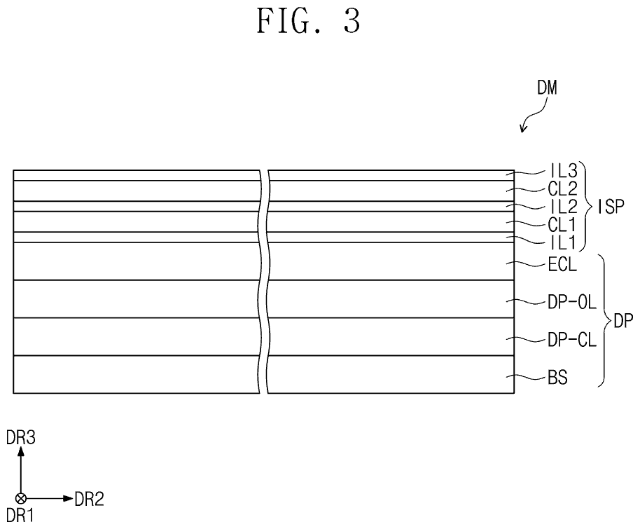

FIG. 3 is a cross-sectional view of the display module according to an embodiment of the present disclosure.

Referring to FIG. 3, the display module DM may include the display panel DP and the input sensing unit ISP. The input sensing unit ISP may be disposed on the display panel DP. The input sensing unit ISP may be disposed directly on the display panel DP. In the present embodiment, the expression “the input sensing unit ISP is disposed directly on the display panel DP” includes that the input sensing layer ISP may be formed on the display panel DP through successive processes and the input sensing unit ISP may be coupled with the display panel DP without employing a separate adhesive layer. That is, components of the input sensing unit ISP may be formed on a base surface provided by the display panel DP.

The display panel DP may display images in response to electrical signals. The display panel DP according to an embodiment may be a light-emitting type display panel. However the display panel DP is not limited thereto. For instance, the display panel DP may be an organic light emitting display panel, an inorganic light emitting display panel, or a quantum dot light emitting display panel. A light emitting layer of the organic light emitting display panel may include an organic light emitting material. A light emitting layer of the inorganic light emitting display panel may include an inorganic light emitting material. A light emitting layer of the quantum dot light emitting display panel may include a quantum dot or a quantum rod. Hereinafter, the organic light emitting display panel will be described as an example of the display panel DP.

The display panel DP may include a base substrate BS, a circuit element layer DP-CL, a light emitting element layer DP-OL, and an encapsulation layer ECL, which may be sequentially stacked in the third direction DR3.

The base substrate BS may be a rigid substrate or a flexible substrate that is bendable, foldable, or rollable. As an example, the base substrate BS may be a glass substrate, a metal substrate, or a polymer substrate. The base substrate BS may provide a base surface on which the circuit element layer DP-CL is disposed.

The base substrate BS may include an inorganic layer, an organic layer, or a composite material layer. The base substrate BS may have a single-layer or multi-layer structure. As an example, the base substrate BS having the multi-layer structure may include synthetic resin layers and an inorganic layer having a single-layer or multi-layer structure and disposed between the synthetic resin layers. The synthetic resin layer may include an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, or a perylene-based resin, however, materials for the synthetic resin layer is not limited thereto or thereby.

The circuit element layer DP-CL may be disposed on the base substrate BS. The circuit element layer DP-CL may include at least one insulating layer, a semiconductor pattern, and a conductive pattern. The insulating layer, the semiconductor pattern, and the conductive pattern included in the circuit element layer DP-CL may form driving elements such as transistors, signal lines, and pads.

The light emitting element layer DP-OL may be disposed on the circuit element layer DP-CL. The light emitting element layer DP-OL may include light emitting elements each emitting a light. For example, each light emitting element may include an organic light emitting element, an inorganic light emitting element, a micro-light emitting diode (LED), or a nano-LED. The light emitting elements of the light emitting element layer DP-OL may be electrically connected to the driving elements of the circuit element layer DP-CL and may emit the light in response to electrical signals provided from the driving elements.

The encapsulation layer ECL may be disposed on the light emitting element layer DP-OL and may encapsulation the light emitting elements. The encapsulation layer ECL may include at least one thin film to increase an optical efficiency of the light emitting element layer DP-OL or to protect the light emitting element layer DP-OL. As an example, the encapsulation layer ECL may include at least one from among an inorganic layer and an organic layer. The inorganic layer of the encapsulation layer ECL may protect the light emitting elements from moisture and oxygen. The organic layer of the encapsulation layer ECL may protect the light emitting elements from a foreign substance such as dust particles.

The input sensing unit ISP may sense the external input and may provide an input signal including coordinate information of the external input to the display panel DP to allow the display panel DP to display the image corresponding to the external input. The input sensing unit ISP may perform the sensing in various ways, such as through a capacitive method, a resistive method, an infrared ray method, a sonic method, a pressure method, or the like. However, embodiments of the present disclosure are not limited thereto, and the input sensing unit ISP may perform the sensing using various other methods that enable the input sensing unit ISP to sense the external input. In the present embodiment, as an example, the input sensing unit ISP will be described as an input sensing panel that may perform the sensing using the capacitive method.

The input sensing unit ISP may include a base layer IL1, a first sensing conductive layer CL1, a first sensing insulating layer IL2, a second sensing conductive layer CL2, and a second sensing insulating layer IL3. The base layer IL1 of the input sensing unit ISP may be in contact with the encapsulation layer ECL. However, embodiments of the present disclosure are not limited thereto or thereby, and at least one from among the base layer IL1 and the second sensing insulating layer IL3 may be omitted.

Each of the first sensing conductive layer CL1 and the second sensing conductive layer CL2 may have a single-layer or multi-layer structure. The conductive layer having the multi-layer structure may include two or more layers of transparent conductive layers and metal layers. The conductive layer having the multi-layer structure may include metal layers including different metals from each other. The transparent conductive layer may include at least one from among indium tin oxide (ITO), indium zinc oxide (IZO), zinc oxide (ZnO), indium tin zinc oxide (ITZO), PEDOT, metal nanowire, and graphene. The metal layer may include at least one from among molybdenum, silver, titanium, copper, aluminum, and alloys thereof. As an example, each of the first sensing conductive layer CL1 and the second sensing conductive layer CL2 may have a two-layer structure of ITO/copper, or may have a three-layer structure of titanium/aluminum/titanium.

Each of the first sensing conductive layer CL1 and the second sensing conductive layer CL2 may include sensing conductive patterns. The sensing conductive patterns of the first sensing conductive layer CL1 and the second sensing conductive layer CL2 may form sensing electrodes and sensing lines connected to the sensing electrodes included in the input sensing unit ISP.

Each of the base layer IL1, the first sensing insulating layer IL2, and the second sensing insulating layer IL3 may include at least one from among an inorganic layer and an organic layer. As an example, the inorganic layer may include at least one from among aluminum oxide, titanium oxide, silicon oxide, silicon oxynitride, zirconium oxide, and hafnium oxide, and the organic layer may include at least one from among an acrylic-based resin, a methacrylic-based resin, a polyisoprene-based resin, a vinyl-based resin, an epoxy-based resin, a urethane-based resin, a cellulose-based resin, a siloxane-based resin, a polyimide-based resin, a polyamide-based resin, and a perylene-based resin. However, materials for the inorganic layer and the organic layer are not limited to the above-described materials. According to an embodiment, the base layer IL1 may include an inorganic layer, and the first sensing insulating layer IL2 and the second sensing insulating layer IL3 may include an organic layer. However, embodiments of the present disclosure are not limited thereto or thereby.

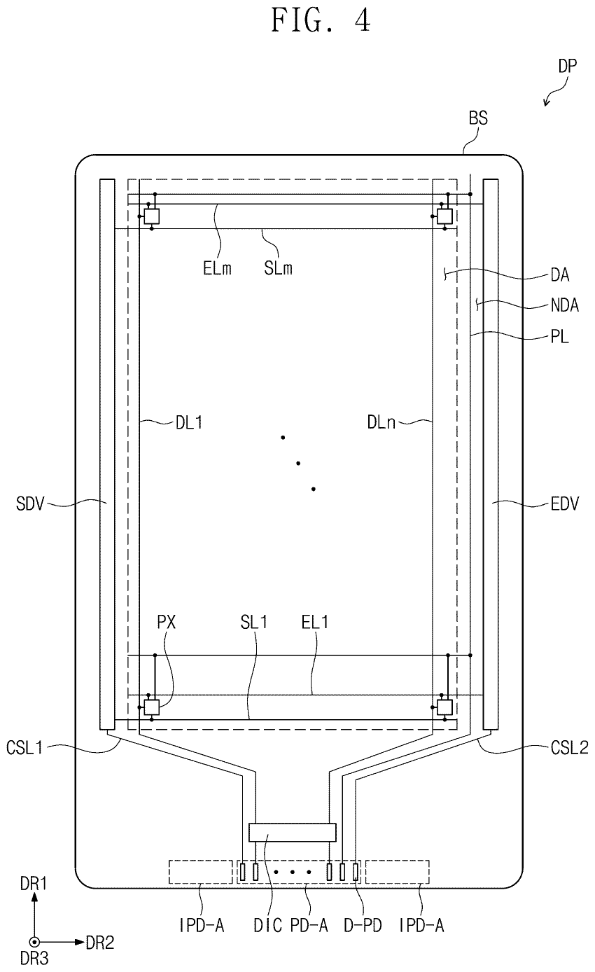

FIG. 4 is a plan view of the display panel according to an embodiment of the present disclosure.

Referring to FIG. 4, the display panel DP may include the base substrate BS, pixels PX, signal lines (e.g., scan lines SL1 to SLm, data lines DL1 to DLn, emission lines EL1 to ELm, a first control line CSL1, a second control line CSL2, and a power line PL) electrically connected to the pixels PX, a scan driver SDV, an emission driver EDV, a driving chip DIC, and display pads D-PD.

The base substrate BS may provide the base surface on which electrical elements and lines of the display panel DP are arranged. The base substrate BS may include a display area DA. The display area DA may be an area in which light emitting elements of the pixels PX are arranged. Accordingly, the pixels PX may display the images through the display area DA. The display area DA may correspond to the active area AA (refer to FIG. 2) of the display module DM (refer to FIG. 2) and may overlap the transmission area TA (refer to FIG. 2) of the window WM (refer to FIG. 2).

An area other than the display area DA may be defined as a non-display area NDA. The non-display area NDA may be adjacent to the display area DA, and the images may not be displayed through the non-display area NDA. The non-display area NDA may surround the display area DA. The scan driver SDV, the emission driver EDV, the driving chip DIC, and the display pads D-PD electrically connected to the signal lines (e.g., the scan lines SL1 to SLm, the data lines DL1 to DLn, the emission lines EL1 to ELm, the first control line CSL1, the second control line CSL2, and the power line PL) may be arranged in the non-display area NDA to drive the pixels PX. The signal lines (e.g., the scan lines SL1 to SLm, the data lines DL1 to DLn, the emission lines EL1 to ELm, the first control line CSL1, the second control line CSL2, and the power line PL) electrically connected to the pixels PX may extend to the non-display area NDA and may be arranged in the non-display area NDA.

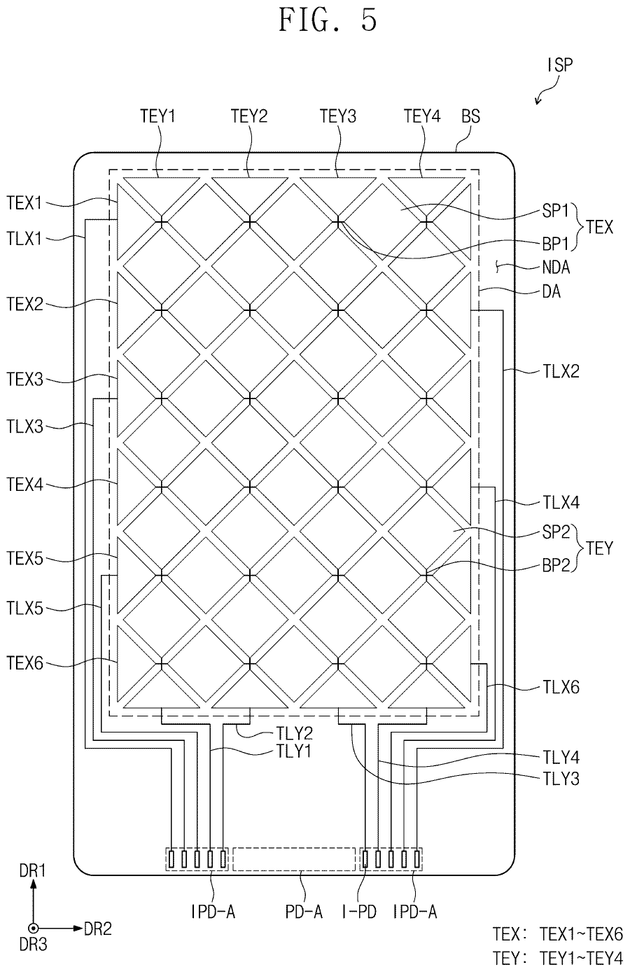

An area in which the display pads D-PD are arranged and an area in which sensing pads I-PD (refer to FIG. 5) are arranged may be referred to as a display pad area PD-A and a sensing pad area IPD-A, respectively. FIG. 4 shows the structure in which the display pad area PD-A and the sensing pad area IPD-A are distinguished from each other in the second direction DR2 as a non-limiting example. As an example, the sensing pad areas IPD-A may be formed at opposite sides of the display pad area PD-A to be spaced apart in the second direction DR2, with the display pad area PD-A positioned in a central region. However, embodiments of the present disclosure are not limited thereto or thereby, and arrangement positions of the display pads D-PD and the sensing pads I-PD (refer to FIG. 5) may be changed in various ways.

The connection circuit board CF (refer to FIG. 2) may be disposed on the area where the display pads D-PD and the sensing pads I-PD (refer to FIG. 5) are arranged and may be electrically connected the display pads D-PD and the sensing pads I-PD (refer to FIG. 5). As the connection circuit board CF arranged adjacent to a lower end of the non-display area NDA is bent, a portion of the connection circuit board CF and the main circuit board MB may be disposed above the rear surface of the display panel DP. Since the portion of the connection circuit board CF and the main circuit board MB are disposed under the display panel DP when viewed from the front surface of the electronic device ED (refer to FIG. 2), a bezel area of the electronic device ED (refer to FIG. 2) may be reduced.

Each of the pixels PX may include a pixel driving circuit including a plurality of transistors (e.g., a switching transistor, a driving transistor, etc.), and at least one capacitor and the light emitting element electrically connected to the pixel driving circuit. Each of the pixels PX may emit a light in response to electrical signals applied thereto and may display the image through the display area DA. According to an embodiment, some of the pixels PX may include a transistor disposed in the non-display area NDA, but embodiments of the present disclosure are not limited thereto.

The scan driver SDV and the emission driver EDV may be disposed in the non-display area NDA adjacent to a side surface of the display area DA. The driving chip DIC may be disposed in the non-display area NDA adjacent to a lower end of the display area DA. According to an embodiment, the driving chip DIC may be mounted on the non-display area NDA of the display panel DP and may be provided in an integrated circuit chip. However, embodiments of the present disclosure are not limited thereto or thereby, and the driving chip DIC may be mounted on the connection circuit board CF (refer to FIG. 2).

The signal lines may include a plurality of scan lines SL1 to SLm, a plurality of data lines DL1 to DLn, a plurality of emission lines EL1 to ELm, a first control line CSL1, a second control line CSL2, and a power line PL. Each of m and n is a natural number.

The data lines DL1 to DLn may be insulated from the scan lines SL1 to SLm and the emission lines EL1 to ELm while intersecting the scan lines SL1 to SLm and the emission lines EL1 to ELm. As an example, the scan lines SL1 to SLm may extend in the second direction DR2 and may be electrically connected to the scan driver SDV. The data lines DL1 to DLn may extend in the first direction DR1 and may be electrically connected to the driving chip DIC. The emission lines EL1 to ELm may extend in the second direction DR2 and may be electrically connected to the emission driver EDV.

The power line PL may include a portion extending in the first direction DR1 and a portion extending in the second direction DR2. The portion of the power line PL extending in the first direction DR1 and the portion of the power line PL extending in the second direction DR2 may be disposed at a different layer or may be provided integrally with each other and may be disposed at the same layer. The portion of the power line PL extending in the second direction DR2 may be electrically connected to the pixels PX and the portion of the power line PL extending in the first direction DR1. The portion of the power line PL extending in the first direction DR1 may be disposed in the non-display area NDA and may be electrically connected to the display pads D-PD. The power line PL may apply a power voltage to the pixels PX.

The first control line CSL1 may be electrically connected to the scan driver SDV and may extend in the second direction DR2. The second control line CSL2 may be electrically connected to the emission driver EDV and may extend in the second direction DR2.

The display pads D-PD may be disposed in the non-display area NDA adjacent to the lower end of the display area DA. The display pads D-PD may be disposed closer than the driving chip DIC to a lower end of the base substrate BS. The display pads D-PD may be spaced apart from each other in the second direction DR2. The power line PL, the first control line CSL1, and the second control line CSL2 may be electrically connected to corresponding display pads D-PD among the display pads D-PD, respectively. The data lines DL1 to DLn may be connected to the corresponding display pads D-PD among the display pads D-PD via the driving chip DIC, respectively.

The display pads D-PD may be electrically connected to the connection circuit board CF (refer to FIG. 2) by an adhesive layer, and the electrical signal provided from the connection circuit board CF may be applied to the display panel DP through the display pads D-PD. However, a connection structure between the display pads D-PD and the connection circuit board CF is not limited thereto or thereby.

The scan driver SDV may generate a plurality of scan signals in response to a scan control signal. The scan signals may be applied to the pixels PX via the scan lines SL1 to SLm. The driving chip DIC may generate a plurality of data voltages corresponding to image signals in response to a data control signal. The data voltages may be applied to the pixels PX via the data lines DL1 to DLn. The emission driver EDV may generate a plurality of emission signals in response to an emission control signal. The emission signals may be applied to the pixels PX via the emission lines EL1 to ELm.

The pixels PX may receive the data voltages in response to the scan signals. The pixels PX may emit a light having a luminance corresponding to the data voltages in response to the emission signals, and thus, the image may be displayed. An emission time of the pixels PX may be controlled by the emission signals.

FIG. 5 is a plan view of the input sensing unit according to an embodiment of the present disclosure. For the convenience of explanation, FIG. 5 schematically shows components of the input sensing unit ISP disposed on the base substrate BS.

The input sensing unit ISP may perform sensing using a mutual capacitance method. Referring to FIG. 5, the input sensing unit ISP may include first sensing electrodes TEX (e.g., first sensing electrodes TEX1 to TEX6), second sensing electrodes TEY (e.g., second sensing electrodes TEY1 to TEY4), first sensing lines TLX1 to TLX6, second sensing lines TLY1 to TLY4, and the sensing pads I-PD. However, embodiments of the present disclosure are not limited thereto or thereby, and according to an embodiment, the input sensing unit ISP may perform sensing using a self-capacitance method.

The first sensing electrodes TEX may extend in the second direction DR2 and may be arranged in the first direction DR1. FIG. 5 shows six first sensing electrodes TEX1 to TEX6 as an example. However, the number of the first sensing electrodes TEX included in the input sensing unit ISP is not limited thereto or thereby. One first sensing electrode TEX may include first sensing patterns SP1 arranged in the second direction DR2, and first connection patterns BP1 connecting the first sensing patterns SP1.

The second sensing electrodes TEY may extend in the first direction DR1, and the second sensing electrodes TEY may be arranged in the second direction DR2. FIG. 5 shows four second sensing electrodes TEY1 to TEY4 as an example. However, the number of the second sensing electrodes TEY included in the input sensing unit ISP is not limited thereto or thereby. One second sensing electrode TEY may include second sensing patterns SP2 arranged in the first direction DR1, and second connection patterns BP2 connecting the second sensing patterns SP2.

The first sensing electrodes TEX may be electrically insulated from the second sensing electrodes TEY. The input sensing unit ISP may sense the external input based on a variation in capacitance between the first sensing electrodes TEX and the second sensing electrodes TEY. The first sensing electrodes TEX and the second sensing electrodes TEY may be disposed in an area corresponding to (e.g., overlapping with) the display area DA of the base substrate BS. Accordingly, the electronic device ED (refer to FIG. 1) may display the image through the display area DA and, substantially simultaneously, may sense the external input applied to the display area DA.

The first sensing lines TLX1 to TLX6 may be arranged in the non-display area NDA and may be electrically connected to the first sensing electrodes TEX1 to TEX6, respectively. Some of the first sensing lines TLX1 to TLX6 may be arranged in the non-display area NDA adjacent to a left side of the display area DA, and the other of the first sensing lines TLX1 to TLX6 may be arranged in the non-display area NDA adjacent to a right side of the display area DA. As an example, the first sensing lines TLX1, TLX3, and TLX5 connected to the first sensing electrodes TEX1, TEX3, and TEX5 arranged in odd-numbered rows may be respectively connected to left sides of the first sensing electrodes TEX1, TEX3, and TEX5, and the first sensing lines TLX2, TLX4, and TLX6 connected to the first sensing electrodes TEX2, TEX4, and TEX6 arranged in even-numbered rows may be connected to right sides of the first sensing electrodes TEX2, TEX4, and TEX6. However, the arrangement of the first sensing lines TLX1 to TLX6 is not limited thereto or thereby, and according to an embodiment, all the first sensing lines TLX1 to TLX6 may be arranged in the non-display area NDA adjacent to the left side of the display area DA or all the first sensing lines TLX1 to TLX6 may be arranged in the non-display area NDA adjacent to the right side of the display area DA.

The first sensing lines TLX1 to TLX6 may extend in the second direction DR2. The first sensing lines TLX1 to TLX6 may be electrically connected to the sensing pads I-PD, respectively.

The second sensing lines TLY1 to TLY4 may be arranged in the non-display area NDA and may be electrically connected to the second sensing electrodes TEY1 to TEY4, respectively. Some of the second sensing lines TLY1 to TLY4 may be arranged adjacent to a left side of the non-display area NDA, and the other of the second sensing lines TLY1 to TLY4 may be arranged adjacent to a right side of the non-display area NDA. As an example, the second sensing lines TLY1 and TLY2 electrically connected to the second sensing electrodes TEY1 and TEY2 arranged at a left side in the second direction DR2 among the second sensing electrodes TEY1 to TEY4 may be arranged adjacent to the left side of the display area DA, and the second sensing lines TLY3 and TLY4 electrically connected to the second sensing electrodes TEY3 and TEY4 arranged at a right side in the second direction DR2 among the second sensing electrodes TEY1 to TEY4 may be arranged at the right side of the display area DA. However, the arrangement of the second sensing lines TLY1 to TLY4 is not limited thereto or thereby.

The second sensing lines TLY1 to TLY4 may extend in the first direction DR1 and/or the second direction DR2. The second sensing lines TLY1 to TLY4 may be electrically connected to the sensing pads I-PD, respectively.

Some of the sensing pads I-PD may be arranged in an area adjacent to a left side of the display pad area PD-A, and the other of the sensing pads I-PD may be arranged in an area adjacent to a right side of the display pad area PD-A. As an example, the sensing pads I-PD may be divided into two groups spaced apart from each other, and the display pad area PD-A may be disposed between the two groups. However, the arrangement of the sensing pads I-PD is not limited thereto or thereby.

The sensing pads I-PD may be disposed at the same layer as the display pads D-PD (refer to FIG. 4). The sensing pads I-PD may be disposed at a different layer from the first sensing lines TLX1 to TLX6 and the second sensing lines TLY1 to TLY4, and may be connected to the first sensing lines TLX1 to TLX6 and the second sensing lines TLY1 to TLY4 through contact holes. However, embodiments of the present disclosure are not limited thereto or thereby, and the sensing pads I-PD may be disposed at a different layer from the display pads D-PD (refer to FIG. 4). As an example, the sensing pads I-PD may be disposed at the same layer as the first sensing lines TLX1 to TLX6 and the second sensing lines TLY1 to TLY4, and may be provided integrally with the first sensing lines TLX1 to TLX6 and the second sensing lines TLY1 to TLY4.

The first sensing lines TLX1 to TLX6 and the second sensing lines TLY1 to TLY4 may be disposed at a position higher than a position of components of the display panel DP (refer to FIG. 4) in an area corresponding to the non-display area NDA of the base substrate BS. Accordingly, the first sensing lines TLX1 to TLX6 and the second sensing lines TLY1 to TLY4 may overlap with the components of the display panel DP (refer to FIG. 4) in the non-display area NDA.

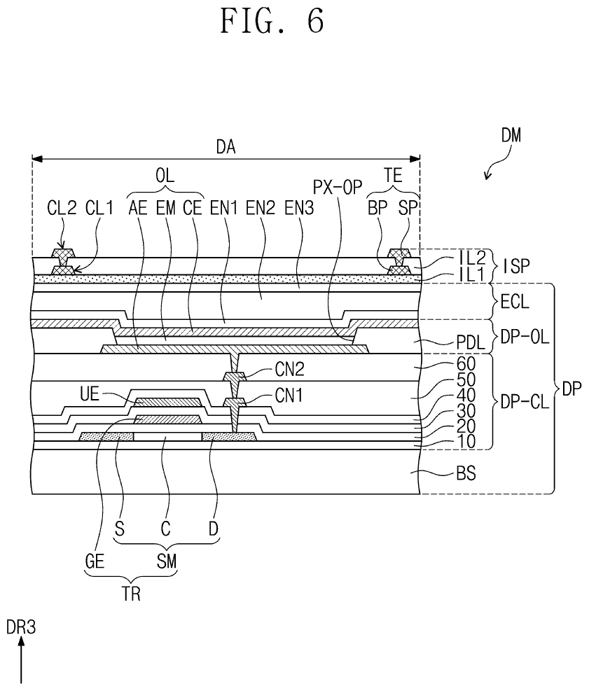

FIG. 6 is a cross-sectional view of the display module according to an embodiment of the present disclosure. As an example, FIG. 6 shows a cross-section of the pixel PX (refer to FIG. 4) disposed in the display area DA.

Referring to FIG. 6, the display module DM may include the display panel DP and the input sensing unit ISP disposed on the display panel DP. The above descriptions may be equally applied to each component.

As described with reference to FIG. 3, the display panel DP may include the base substrate BS, the circuit element layer DP-CL, the light emitting element layer DP-OL, and the encapsulation layer ECL.

The base substrate BS may have an insulating property and may provide the base surface on which components of the display module DM are disposed. The base substrate BS may have flexibility sufficient to be bendable. As an example, the base substrate BS may be bent at a selected curvature.

The circuit element layer DP-CL may include insulating layers, a transistor TR of the pixel PX (refer to FIG. 4), an upper electrode UE, and connection electrodes (e.g., a first connection electrode CN1 and a second connection electrode CN2), which may disposed on the base substrate BS. The insulating layers may include a first insulating layer 10, a second insulating layer 20, a third insulating layer 30, a fourth insulating layer 40, a fifth insulating layer 50, and a sixth insulating layer 60 sequentially stacked on the base substrate BS along the thickness direction (e.g., the third direction DR3). However, the first to sixth insulating layers 10 to 60 included in the circuit element layer DP-CL are not limited thereto or thereby, and may be changed depending on the structure or manufacturing process of the circuit element layer DP-CL.

The first insulating layer 10 may be disposed on the base substrate BS. The first insulating layer 10 may be a barrier layer and/or a buffer layer that prevents a foreign substance from entering from the outside. The first insulating layer 10 may increase an adhesion between the base substrate BS and a semiconductor pattern SM and/or between the base substrate BS and a conductive pattern of the circuit element layer DP-CL. The first insulating layer 10 may include at least one from among a silicon oxide layer and a silicon nitride layer. According to an embodiment, the first insulating layer 10 may include silicon oxide layers and silicon nitride layers alternately stacked with the silicon oxide layers.

The pixel PX (refer to FIG. 4) may be disposed on the base substrate BS. The pixel PX (refer to FIG. 4) may be disposed to correspond to (e.g., be in) the display area DA. The pixel PX (refer to FIG. 4) may include the transistor TR and a light emitting element OL.

The transistor TR may include the semiconductor pattern SM and a gate electrode GE. The semiconductor pattern SM may be disposed on the first insulating layer 10. The semiconductor pattern SM may include a channel C, a source S, and a drain D. The semiconductor pattern SM may include a silicon semiconductor and may include a crystalline silicon semiconductor, a polycrystalline silicon semiconductor, or an amorphous silicon semiconductor. However, embodiments of the present disclosure are not limited thereto or thereby, and the semiconductor pattern SM may include an oxide semiconductor. The semiconductor pattern SM according to an embodiment of the present disclosure may include a variety of materials as long as the semiconductor pattern SM has a semiconductor property.

The semiconductor pattern SM may include a plurality of areas with different electrical properties depending on whether the areas are doped or whether a metal oxide is reduced. As an example, the semiconductor pattern SM may include areas with high conductivity achieved through doping or reduction of metal oxides, and the areas having the high conductivity may serve as the electrode or the signal line of the transistor TR. The areas having the high conductivity may correspond to the source S and the drain D of the transistor TR. The semiconductor pattern SM may include an undoped area with relatively low conductivity, and the area having the low conductivity may correspond to the channel C (or an active region) of the transistor TR.

The second insulating layer 20 may be disposed on the first insulating layer 10 and may cover the semiconductor pattern SM. The gate electrode GE may be disposed on the second insulating layer 20. The second insulating layer 20 may be disposed between the semiconductor pattern SM and the gate electrode GE of the transistor TR. The gate electrode GE may overlap with the channel C of the semiconductor pattern SM when viewed in the plane (e.g., in the third direction DR3). The gate electrode GE may be used as a mask in a process of doping the semiconductor pattern SM. The gate electrode GE may include molybdenum (Mo) with heat resistance, an alloy including molybdenum (Mo), titanium (Ti), an alloy including titanium (Ti), or the like. However, a material of the gate electrode GE is not limited thereto.

The structure of the transistor TR shown in FIG. 6 is merely an example, and the source S or the drain D of the transistor TR may be formed independent from the semiconductor pattern SM. In this case, the source S and the drain D may be in contact with the semiconductor pattern SM or may be connected to the semiconductor pattern SM after penetrating through an insulating layer. In addition, the gate electrode GE may be disposed under the semiconductor pattern SM. The transistor TR according to an embodiment of the present disclosure may have various structures and is not particularly limited.

The second insulating layer 20 and the third to sixth insulating layers 30 to 60 described below may include at least one from among an inorganic layer and an organic layer. As an example, the inorganic layer may include at least one from among aluminum oxide, titanium oxide, silicon oxide, silicon oxynitride, zirconium oxide, and hafnium oxide. The organic layer may include at least one from among an acrylic-based resin, a methacrylic-based resin, a polyisoprene-based resin, a vinyl-based resin, an epoxy-based resin, a urethane-based resin, a cellulose-based resin, a siloxane-based resin, a polyamide-based resin, and a perylene-based resin.

The third insulating layer 30 may be disposed on the second insulating layer 20 and may cover the gate electrode GE. The upper electrode UE may be disposed on the third insulating layer 30. The upper electrode UE may overlap with the gate electrode GE when viewed in the plane (e.g., in the third direction DR3), and the gate electrode GE and the upper electrode UE overlapping with the gate electrode GE may define a capacitor.

The fourth insulating layer 40 may be disposed on the third insulating layer 30 and may cover the upper electrode UE. The connection electrodes may include a first connection electrode CN1 and a second connection electrode CN2. The first connection electrode CN1 may be disposed on the fourth insulating layer 40. The fifth insulating layer 50 may be disposed on the fourth insulating layer 40 and may cover the first connection electrode CN1. The second connection electrode CN2 may be disposed on the fifth insulating layer 50. The sixth insulating layer 60 may be disposed on the fifth insulating layer 50 and may cover the second connection electrode CN2. According to an embodiment, at least one from among the fifth insulating layer 50 and the sixth insulating layer 60 may include an organic layer and may compensate for a step difference between components disposed under the fifth insulating layers 50 and the sixth insulating layer 60 to provide a flat upper surface.

The first connection electrode CN1 may be electrically connected to the semiconductor pattern SM via a contact hole defined through the second to fourth insulating layers 20 to 40. The second connection electrode CN2 may be electrically connected to the first connection electrode CN1 via a contact hole defined through the fifth insulating layer 50.

Each of the first connection electrode CN1 and the second connection electrode CN2 may include a conductive material. Each of the first connection electrode CN1 and the second connection electrode CN2 may include gold, silver, copper, aluminum, platinum, molybdenum, titanium, and alloys thereof. At least one from among the first connection electrode CN1 and the second connection electrode CN2 may have a multi-layer structure of conductive layers. As an example, at least one from among the first connection electrode CN1 and the second connection electrode CN2 may have a three-layer structure of titanium/aluminum/titanium. However, embodiments of the present disclosure are not limited thereto or thereby.

At least one from among the first connection electrode CN1 and the second connection electrode CN2 may be omitted depending on embodiments of the circuit element layer DP-CL. According to an embodiment, an additional connection electrode that connects the transistor TR and the light emitting element OL may be further provided depending on embodiments of the circuit element layer DP-CL. The method of electrically connecting the light emitting element OL and the transistor TR may be changed in various ways depending on the number of the insulating layers disposed between the light emitting element OL and the transistor TR. However, embodiments of the present disclosure are not limited thereto or thereby.

The light emitting element layer DP-OL may include the light emitting element OL and a pixel definition layer PDL. The light emitting element OL and the pixel definition layer PDL may be disposed on the sixth insulating layer 60. The light emitting element OL may include a first electrode AE, a light emitting layer EM, and a second electrode CE.

The first electrode AE may be electrically connected to the second connection electrode CN2 via a contact hole defined through the sixth insulating layer 60. The first electrode AE may be electrically connected to the transistor TR through the first connection electrode CN1 and the second connection electrode CN2.

A pixel opening PX-OP may be defined through the pixel definition layer PDL to expose at least a portion of the first electrode AE. The portion of the first electrode AE, which is exposed through the pixel definition layer PDL, may correspond to a light emitting area. The pixel definition layer PDL may include an inorganic layer, an organic layer, or a composite material layer. According to an embodiment, the pixel definition layer PDL may further include a black pigment or a black dye.

The light emitting layer EM may be disposed on the first electrode AE. The light emitting layer EM may emit a light having a selected color. The light emitting layer EM may be disposed to correspond to (e.g., be in) the pixel opening PX-OP defined through the pixel definition layer PDL. Each of the light emitting element OL and the pixel opening PX-OP may be provided in plural, and the light emitting layers EM of the light emitting elements OL may be arranged to correspond to (e.g., be in) the pixel openings PX-OP, respectively, and may be spaced apart from each other. However, embodiments of the present disclosure are not limited thereto or thereby, and according to an embodiment, the light emitting layers EM of the light emitting elements OL may be provided integrally with each other as a common layer.

The second electrode CE may be disposed on the light emitting layer EM and the pixel definition layer PDL. The second electrode CE may be provided as a common electrode that is commonly disposed over the pixels PX (refer to FIG. 4).

The light emitting element OL may further include at least one from among a hole control region disposed between the first electrode AE and the light emitting layer EM, and an electron control region disposed between the light emitting layer EM and the second electrode CE. The hole control region may include at least one from among a hole generation layer, a hole transport layer, and an electron block layer, and the electron control region may include at least one from among an electron generation layer, an electron transport layer, and a hole block layer.

The encapsulation layer ECL may be disposed on the light emitting element layer DP-OL. The encapsulation layer ECL may be disposed on the light emitting element OL and the pixel definition layer PDL to encapsulate the light emitting element OL. The encapsulation layer ECL may include at least one from among an inorganic layer and an organic layer. In the present embodiment, the encapsulation layer ECL may include a first inorganic layer EN1, a second inorganic layer EN3, and an organic layer EN2 disposed between the first inorganic layer EN1 and the second inorganic layer EN3. However, the encapsulation layer ECL is not limited thereto or thereby.

The first inorganic layer EN1 may be disposed on the second electrode CE, and the organic layer EN2 and the second inorganic layer EN3 may be sequentially stacked on the first inorganic layer EN1 in the thickness direction (e.g., the third direction DR3) of the display panel DP. The first inorganic layer EN1 and the second inorganic layer EN3 may protect the light emitting element OL from moisture or oxygen from the outside. As an example, each of the first inorganic layer EN1 and the second inorganic layer EN3 may include at least one from among silicon nitride, silicon oxynitride, silicon oxide, titanium oxide, and aluminum oxide. However, the material of the first inorganic layer EN1 and the second inorganic layer EN3 is not limited thereto or thereby. The organic layer EN2 may prevent a foreign substance from entering the light emitting element OL and may compensate for a step difference between components disposed under the organic layer EN2. As an example, the organic layer EN2 may include an acrylic-based organic material. However, the material of the organic layer EN2 is not limited thereto or thereby.

The input sensing unit ISP may be disposed on the display panel DP. The input sensing unit ISP may include the base layer IL1, the first sensing insulating layer IL2, the first sensing conductive layer CL1, and the second sensing conductive layer CL2. The input sensing unit ISP may further include the second sensing insulating layer IL3 as shown in FIG. 3. The above descriptions may be equally applied to each component.

The base layer IL1 may be in contact with an uppermost layer of the encapsulation layer ECL. As an example, the base layer IL1 may be in contact with the second inorganic layer EN3 of the encapsulation layer ECL. The base layer IL1 of the input sensing unit ISP may be directly formed on a base surface of the encapsulation layer ECL. However, embodiments of the present disclosure are not limited thereto or thereby, and according to an embodiment, the base layer IL1 may be omitted according to embodiments. In this case, the first sensing conductive layer CL1 of the input sensing unit ISP may be in contact with the encapsulation layer ECL.

The first sensing conductive layer CL1 may be disposed on the base layer IL1, and the second sensing conductive layer CL2 may be disposed on the first sensing insulating layer IL2. The first sensing conductive layer CL1 and the second sensing conductive layer CL2 may form a sensing electrode TE. The sensing electrode TE may correspond to (e.g., be) one of the first sensing electrode TEX and the second sensing electrode TEY (refer to FIG. 5). As an example, the first sensing conductive layer CL1 may include a connection pattern BP of the sensing electrode TE, and the second sensing conductive layer CL2 may include a sensing pattern SP of the sensing electrode TE. However, embodiments of the present disclosure are not limited thereto or thereby. The first sensing conductive layer CL1 may include the sensing pattern SP, and the second sensing conductive layer CL2 may include the connection pattern BP.

The connection pattern BP may correspond to (e.g., be) the first connection pattern BP1 (refer to FIG. 5) or the second connection pattern BP2 (refer to FIG. 5), and the sensing pattern SP may correspond to (e.g., be) the first sensing pattern SP1 (refer to FIG. 5) or the second sensing pattern SP2 (refer to FIG. 5). The connection pattern BP may be disposed at a layer different from the sensing pattern SP and may be connected to the sensing pattern SP via a contact hole defined through the first sensing insulating layer IL2. However, embodiments of the present disclosure are not limited thereto or thereby. According to an embodiment, the connection pattern BP and the sensing pattern SP may be disposed at the same layer and may be provided integrally with each other.

The sensing electrode TE may be a pattern with a mesh shape and may be disposed to correspond to an area where the pixel definition layer PDL is disposed. However, embodiments of the present disclosure are not limited thereto or thereby. According to an embodiment, the sensing electrode TE may be provided as a pattern with a single shape overlapping the light emitting element OL, and in this case, the sensing electrode TE may include a transparent conductive material.

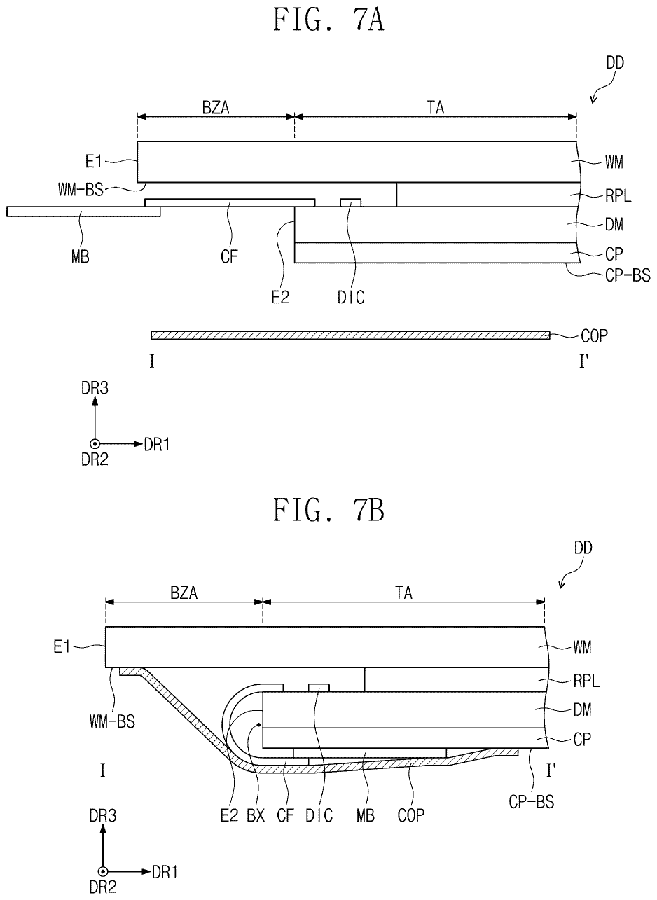

FIGS. 7A and 7B are cross-sectional views of a display device according to an embodiment of the present disclosure. In detail, FIG. 7A is a cross-sectional view of the display device DD taken along a line I-I′ of FIG. 2, and FIG. 7B is a cross-sectional view of the display device DD in which the circuit board CF is bent. Hereinafter, repeated descriptions may be omitted.

Referring to FIGS. 7A and 7B, the connection circuit board CF may be bent at a selected curvature in a direction toward the rear surface of the display module DM. As an example, the connection circuit board CF may be bent about a bending axis BX parallel to the second direction DR2. In this case, the main circuit board MB may be disposed on the rear surface of the display module DM. In detail, the main circuit board MB may be disposed on a rear surface CP-BS of the cover panel CP.

The window WM may include a first edge E1, and the display module DM may include a second edge E2. According to an embodiment of the present disclosure, the first edge E1 of the window WM and the second edge E2 of the display module DM may not be aligned (e.g., overlapped) with each other in the third direction DR3. As an example, the first edge E1 of the window WM may protrude more outward than the second edge E2 of the display module DM in a direction opposite to the first direction DR1. Accordingly, when viewed in the third direction DR3, a portion of a lower surface WM-BS of the window WM may not overlap with the display module DM.

According to an embodiment of the present disclosure, the cover part COP may be disposed under the cover panel CP and may cover the connection circuit board CF and the main circuit board MB. Referring to FIG. 7B, one side of the cover part COP may be in contact with a portion of the lower surface WM-BS overlapping with the bezel area BZA of the window WM, and the other side of the cover part COP, which is opposite to the one side of the cover part COP, may be in contact with the rear surface CP-BS of the cover panel CP. The cover part COP may be attached to the lower surface WM-BS of the window WM and the rear surface CP-BS of the cover panel CP. According to embodiments of the present disclosure, a separate adhesive may be disposed between the cover part COP and the lower surface WM-BS of the window WM and between the cover part COP and the rear surface CP-BS of the cover panel CP. As the cover part COP extends to the lower surface WM-BS of the window WM, the cover part COP may cover (e.g., overlap with) the second edge E2 of the display module DM and may protect the second edge E2 of the display module DM, and thus, a durability of the display device DD may be improved.

The cover part COP may cover the connection circuit board CF and the main circuit board MB. As an example, when viewed in the third direction DR3, the cover part COP may overlap with an entirety of the connection circuit board CF and the main circuit board MB, and the connection circuit board CF and the main circuit board MB may not be exposed to the outside. As an example, the cover part COP may be in contact with a portion of the connection circuit board CF and a portion of the main circuit board MB. The cover part COP may protect the portion of the connection circuit board CF and the main circuit board MB from external static electricity. The cover part COP may protect the connection circuit board CF and the main circuit board MB from radio waves or static electricity generated from the electronic module ELM (refer to FIG. 2) such as, for example, the antenna.

According to an embodiment of the present disclosure, the cover part COP may cover (e.g., overlap with) the driving chip DIC. In detail, the cover part COP may cover (e.g., overlap with) the driving chip DIC in the direction opposite to the first direction DR1. The cover part COP may protect the driving chip DIC from the external static electricity. The cover part COP may include a metal material with high conductivity to absorb or reflect the external radio waves. As an example, the cover part COP may include iron or nickel to absorb an external magnetic field, or may include copper or aluminum to reflect the external magnetic field. That is, as the cover part COP covers the driving chip DIC in the direction opposite to the first direction DR1, the driving chip DIC may be protected from the external static electricity. In detail, the cover part COP may protect the driving chip DIC from the radio waves or static electricity generated from the electronic module ELM (refer to FIG. 2) such as, for example, the antenna. In addition, the cover part COP may shield the driving chip DIC to prevent the magnetic field generated from the driving chip DIC from being emitted to the outside. In FIGS. 7A and 7B, the cover part COP has a single-layer structure. However, the cover part COP may have a multi-layer structure.

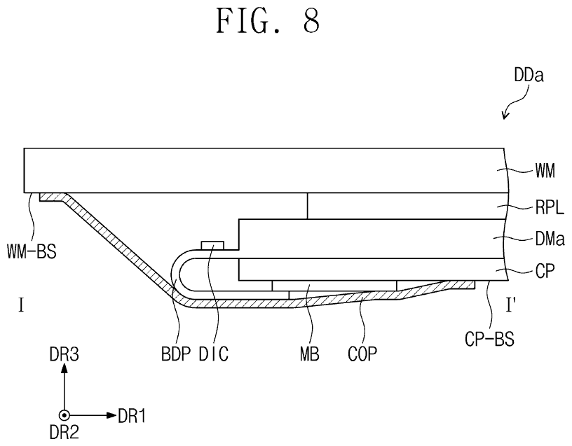

FIG. 8 is a cross-sectional view of a display device according to an embodiment of the present disclosure.

Referring to FIG. 8, the display device DDa may include a display module DMa that is bendable. As an example, the display module DMa may include a bending portion BDP that is bendable. A main circuit board MB may be in direct contact with and electrically connected to the display module DMa. The cover part COP may be in contact with the bending portion BDP of the display module DMa to cover at least a portion of the bending portion BDP.

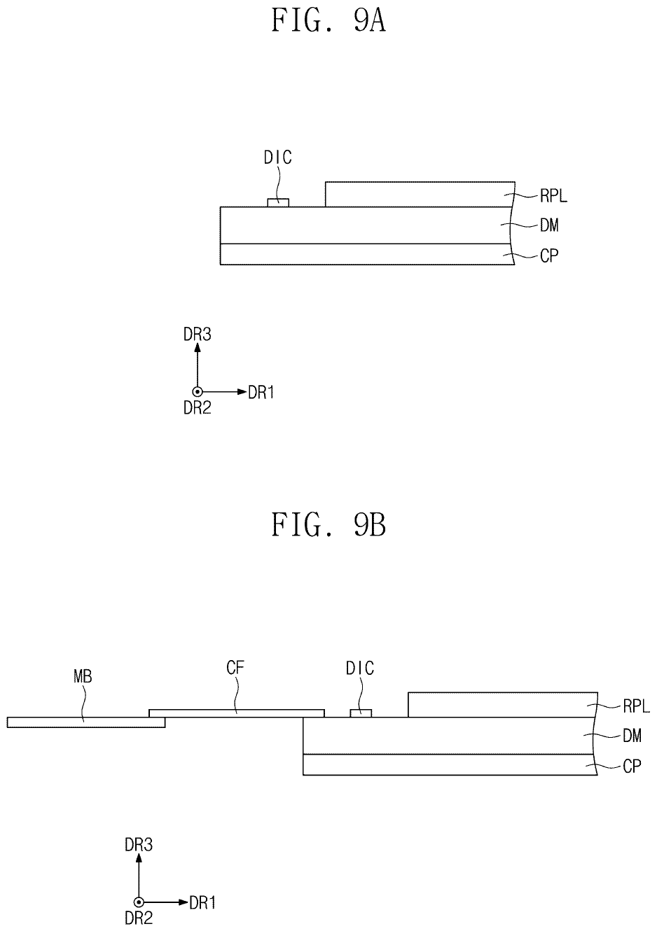

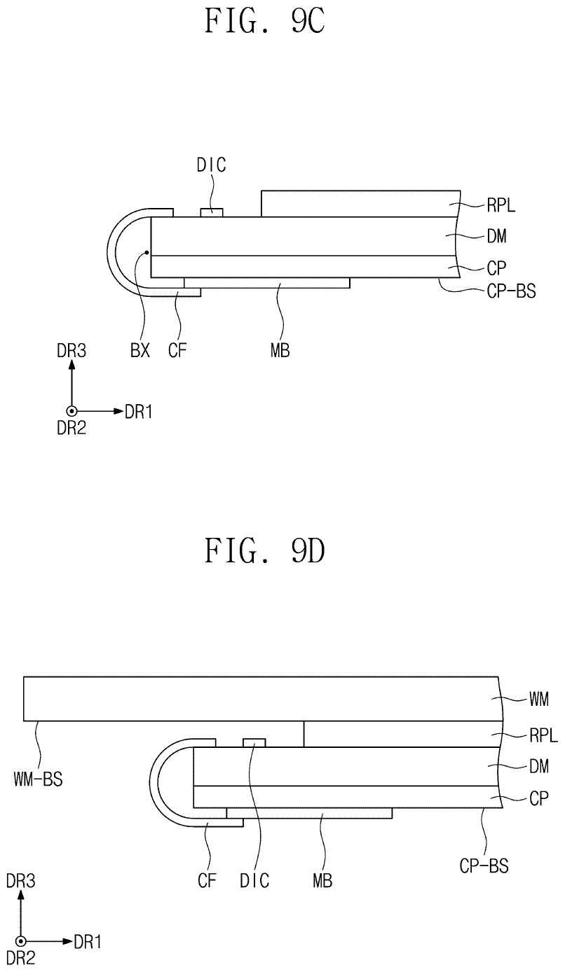

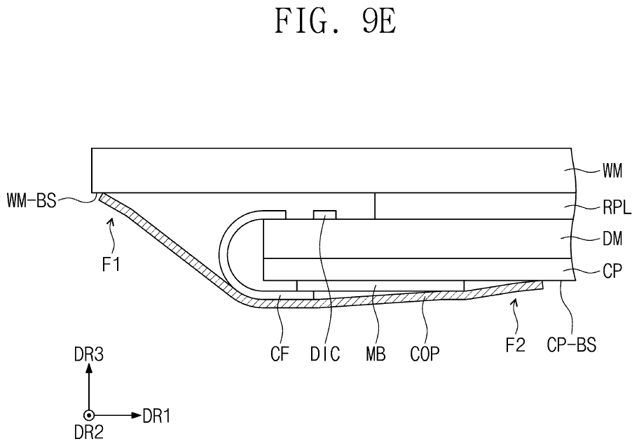

FIGS. 9A to 9E are process views of a method of manufacturing a display device according to an embodiment of the present disclosure. In detail, FIGS. 9A to 9E are process views of the manufacturing method of the display device DD shown in FIG. 7B. Hereinafter, repeated descriptions of the same elements as those described with reference to FIGS. 7A and 7B may be omitted.

Referring to FIG. 9A, a process of providing (e.g., forming) the display module DM on the cover panel CP, a process of providing (e.g., forming) the optical layer RPL on the display module DM, and a process of providing (e.g., forming) the driving chip DIC on the display module DM may be performed. The providing (e.g., forming) of the driving chip DIC may be performed after the providing (e.g., forming) of the optical layer RPL. However, embodiments of the present disclosure are not limited thereto or thereby, and the providing (e.g., forming) of the optical layer RPL may be performed after the providing (e.g., forming) of the driving chip DIC.

Referring to FIG. 9B, a process of providing (e.g., forming) the connection circuit board CF on one side of the display module DM and a process of providing (e.g., forming) the main circuit board MB to be electrically connected to the connection circuit board CF may be performed. According to some embodiments, the providing (e.g., forming) of the connection circuit board CF on the one side of the display module DM may include connecting the display pads D-PD (refer to FIG. 4) disposed on the display module DM to the connection circuit board CF.

Referring to FIG. 9C, a process of bending the connection circuit board CF may be performed. The connection circuit board CF may be bent about the bending axis BX at the selected curvature. As an example, the connection circuit board CF may be bent in the direction toward the rear surface of the display module DM with respect to the bending axis BX. As the connection circuit board CF is bent, the main circuit board MB may be disposed on the rear surface of the display module DM. In detail, the main circuit board MB may be disposed on the rear surface CP-BS of the cover panel CP.

Referring to FIGS. 9D and 9E, a process of providing (e.g., forming) the window WM on the optical layer RPL may be performed, and a process of placing the cover part COP to cover the connection circuit board CF and the main circuit board MB may be performed. One side of the cover part COP may be in contact with the lower surface WM-BS of the window WM, and the other side of the cover part COP, which is opposite to the one side of the cover part COP, may be in contact with the rear surface CP-BS of the cover panel CP. A first pressure F1 may be applied to the one side of the cover part COP to attached the one side of the cover part COP to the lower surface WM-BS of the window WM, and a second pressure F2 may be applied to the other side of the cover part COP to attach the other side of the cover part COP to the rear surface CP-BS of the cover panel CP.

According to an embodiment of the present disclosure, the cover part COP may cover (e.g., overlap with) the driving chip DIC. In detail, the cover part COP may cover (e.g., overlap with) the driving chip DIC in the direction opposite to the first direction DR1. The driving chip DIC may be protected from the external static electricity by the cover part COP.

In a case where the cover part COP is formed before the forming of the window WM and is placed between the window WM and the display module DM, it may be difficult to remove the cover part COP when defects occur in the cover part COP.

According to an embodiment of the present disclosure, the cover part COP may be formed after the window WM is formed on the optical layer RPL. In this case, even when a defect is detected in the cover part COP after inspecting whether the cover part COP is defective, it becomes easier to separate the cover part COP from the lower surface WM-BS of the window WM and the rear surface CP-BS of the cover panel CP, and to reattach the cover part COP to the lower surface WM-BS of the window WM and the rear surface CP-BS of the cover panel CP. As a result, a manufacturing yield of the display device DD (refer to FIG. 2) of the present disclosure may be improved.

Although non-limiting example embodiments of the present disclosure have been described above, it is understood that the present disclosure is not limited to these example embodiments. Various changes and modifications can be made by one ordinary skilled in the art, and the various changes and modifications are included within the spirit and scope of the present disclosure as hereinafter claimed. Therefore, the present disclosure is not limited to any single embodiment described herein.

What is claimed is:

1. A display device comprising:
a display extending at least partially in a first direction and a second direction that crosses the first direction;
a window on the display in a third direction that crosses the first direction and the second direction;
a connection circuit board connected to the display on a first side of the display;
a main circuit board on a rear surface of the display in a fourth direction, opposite to the third direction, and connected to the connection circuit board; and
a cover part overlapping with the connection circuit board and the main circuit board,
wherein a first side of the cover part is in contact with a lower surface of the window in the fourth direction.

2. The display device of claim 1, further comprising a cover panel under the display in the fourth direction.

3. The display device of claim 2, wherein a second side of the cover part, which is opposite to the first side of the cover part, is in contact with a lower surface of the cover panel in the fourth direction.

4. The display device of claim 1, wherein the window comprises a transmission area and a bezel area at least partially surrounding the transmission area, and the second side of the cover part overlaps with the bezel area.

5. The display device of claim 1, further comprising an optical layer between the display and the window.

6. The display device of claim 1, wherein the display comprises:
a display area;
a non-display area at least partially surrounding the display area; and
a driving chip in the non-display area.

7. The display device of claim 6, wherein the window comprises a first edge,
wherein the display comprises a second edge, and
wherein the first edge protrudes more outward than the second edge in the first direction.

8. The display device of claim 7, wherein the cover part overlaps with the driving chip in a fifth direction that is opposite to the first direction.

9. The display device of claim 1, wherein the cover part is in contact with the connection circuit board and the main circuit board.

10. The display device of claim 1, wherein the cover part comprises a metal material.

11. An electronic device comprising:
a housing;
an electronic module in the housing; and
a display device overlapping with the electronic module, the display device comprising:
a display extending at least partially in a first direction and a second direction that crosses the first direction;
a window on the display in a third direction that crosses the first direction and the second direction;
a connection circuit board electrically connected to the display on a first side of the display;
a main circuit board on a rear surface of the display in a fourth direction, opposite to the third direction, and connected to the connection circuit board; and
a cover part overlapping with the connection circuit board and the main circuit board,
wherein a first side of the cover part is in contact with a lower surface of the window in the fourth direction.

12. The electronic device of claim 11, wherein the electronic module comprises an antenna,
wherein the display device further comprises a driving chip at one side of the display, and
wherein the cover part blocks exposure of the connection circuit board, the main circuit board, and the driving chip to the antenna.

13. A method of manufacturing a display device, comprising:
connecting a display and a main circuit board with a connection circuit board, wherein the display extends at least partially in a first direction and a second direction that crosses the first direction, the main circuit board is on a rear surface of the display, and the connecting comprises:
connecting the connection circuit board to the display on one side of the display; and
bending the connection circuit board, wherein the connection circuit board, which is bent, connects the display to the main circuit board;
placing a window on the display in a third direction that crosses the first direction and the second direction; and
overlapping the connection circuit board and the main circuit board with a cover part.

14. The method of claim 13, wherein the placing the cover part comprises contacting one side of the cover part to a lower surface of the window in a fourth direction that is opposite to the third direction.

15. The method of claim 14, wherein the cover part is in contact with the connection circuit board and the main circuit board.

16. The method of claim 14, further comprising placing a cover panel under the display in the fourth direction.

17. The method of claim 16, wherein the placing the cover part comprises contacting a second side of the cover part, which is opposite to the first side of the cover part, to a lower surface of the cover panel in the fourth direction.

18. The method of claim 13, further comprising placing an optical layer between the display and the window.

19. The method of claim 13, further comprising placing a driving chip before the placing the window,
wherein the display includes a display area and a non-display area at least partially surrounding the display area, and
wherein the driving chip is in the non-display area.

20. The method of claim 13, further comprising inspecting whether the cover part is defective.
